(19) United States
(12) Patent Application Publication
(10) Pub. No.: US 2026/0122830 A1
(43) Pub. Date: Apr. 30, 2026

(54) Power Distribution System And Power Distribution Cabinet

(71) Applicant: VERTIV CORPORATION, Westerville, OH (US)

(72) Inventors: Ruilong WANG, Xi'an (CN); Xueji ZHOU, Xi'an (CN); Minjie ZHANG, Xi'an (CN); Xing LI, Xi'an (CN); Lei ZHANG, Xi'an (CN)

(73) Assignee: VERTIV CORPORATION, Westerville, OH (US)

(21) Appl. No.: 19/223,270

(22) Filed: May 30, 2025

(30) Foreign Application Priority Data
Oct. 29, 2024 (CN) 202422624550.2

(51) Int. Cl. H05K 7/14; H02B 1/34; H02B 1/56

(52) U.S. Cl. CPC H05K 7/1492; H02B 1/34; H02B 1/565

(57) ABSTRACT

The present disclosure provides a power distribution system and a power distribution cabinet, and relates to the technical field of data centers. The power distribution system includes a power distribution module, a maintenance output module, and an uninterruptible power supply. The power distribution module includes a power distribution general interface and a power distribution output interface. The power distribution output interface of the power distribution module is electrically connected to the maintenance output module, and the maintenance output module is connected to the uninterruptible power supply and a load module. The power distribution output interface outputs electrical energy to the maintenance output module. When the maintenance output module is in a normal power supply mode, the maintenance output module delivers the electrical energy delivered from the power distribution module to the uninterruptible power supply, and then the electrical energy is delivered to the maintenance output module through the uninterruptible power supply, and the maintenance output module finally delivers the electrical energy to the load module. When the maintenance output module is in a maintenance mode, the maintenance output module directly delivers the electrical energy delivered from the power distribution module to the load module. The power distribution system provided according to the present disclosure has a low failure rate and is easy to maintain.

### CROSS-REFERENCE TO RELATED APPLICATION

The present application claims priority to Chinese Patent Application No. 202422624550.2, titled “POWER DISTRIBUTION SYSTEM AND POWER DISTRIBUTION CABINET”, filed on Oct. 29, 2024, with the China National Intellectual Property Administration, the entire disclosure of which is incorporated herein by reference.

### FIELD

The present disclosure relates to the technical field of data centers, and in particular to a power distribution system and a power distribution cabinet.

### BACKGROUND

With the continuous development of modular data centers, components of the modular data centers are also evolving and iterating. Power distribution systems of the data centers are also developing, and power distribution cabinets have a higher product integration level, a higher intelligent level, is rich in function and more complex, thereby enhancing product competitiveness and better meeting the rapid development requirements of the data centers.

In related arts, a power distribution module in a power distribution cabinet has numerous internally integrated power distribution structures, complex designs, numerous device connection terminals, and thus the probability of failures in the internal of the power distribution module is high. When a failure occurs in the power distribution module, the entire power distribution module must be disassembled for failure diagnosis, troubleshooting and analysis, making a maintenance for the power distribution module complex and costly.

### SUMMARY

The present disclosure provides a power distribution system and a power distribution cabinet, effectively reducing the failure rate of the power distribution system and simplifying maintenance of the power distribution system.

In a first aspect of the present disclosure, a power distribution system is provided. The power distribution system includes a power distribution module, a maintenance output module, and an uninterruptible power supply. The power distribution module includes a main power distribution interface and a power distribution output interface. The power distribution output interface of the power distribution module is electrically connected to the maintenance output module, the maintenance output module is electrically connected to the uninterruptible power supply, and the maintenance output module is further electrically connected to a load module. The power distribution general interface is externally connected to a power supply device, the power distribution output interface outputs electrical energy to the maintenance output module, and the maintenance output module has a normal power supply mode and a maintenance mode. When the maintenance output module is in the normal power supply mode, the maintenance output module delivers the electrical energy delivered from the power distribution module to the uninterruptible power supply, and then the electrical energy is delivered to the maintenance output module through the uninterruptible power supply, and the maintenance output module finally delivers the electrical energy to the load module. When the maintenance output module is in the maintenance mode, the maintenance output module directly delivers the electrical energy delivered from the power distribution module to the load module.

In the power distribution system according to the present disclosure, the power distribution system is divided to the power distribution module, the maintenance output module, and the uninterruptible power supply. The three modules are arranged independently from each other, and the power distribution function for the load is achieved through the cooperation of the three modules. Compared to related technologies where all power distribution functions are integrated into a single module, resulting in all wiring terminals being integrated at a rear side of a power distribution unit, the power distribution system according to the present disclosure is divided to three independent modules, and wiring of the power distribution system is transformed into connections between modules, thereby reducing the wiring complexity of the entire power distribution system. The modular design of the power distribution system further makes configuration of the power distribution system more flexible and low-cost.

In an embodiment, a first circuit and a second circuit are connected between the maintenance output module and the load module, the first circuit and the second circuit are arranged in parallel, the uninterruptible power supply is connected to the first circuit, and the maintenance output module is configured to control on and off of the first circuit and the second circuit.

In an embodiment, the maintenance output module further includes a control switch, the control switch is connected between the first circuit and the second circuit, and the control switch is configured to control the on and off of the first circuit and the second circuit.

In an embodiment, the power distribution system further includes an expansion module. The expansion module has an expansion output interface for connecting a load, and the expansion module and the power distribution module are connected through an expansion circuit, so that the power distribution module is configured to distribute power to the expansion module through the expansion circuit.

In an embodiment, the expansion circuit is connected to the maintenance output module; when the maintenance output module is in the normal power supply mode, the maintenance output module delivers the electrical energy delivered from the power distribution module to the uninterruptible power supply, and then the electrical energy is delivered to the maintenance output module through the uninterruptible power supply, and the maintenance output module finally delivers the electrical energy to the expansion circuit; and
when the maintenance output module is in the maintenance mode, the maintenance output module directly delivers the electrical energy delivered from the power distribution module to the expansion circuit.

In an embodiment, the power distribution system further includes a power supply management module. The power supply management module is connected to the expansion module or the maintenance output module, the power supply management module has multiple power supply output interfaces, the multiple power supply output interfaces are connected to the load module, and the expansion module or the maintenance output module supplies power to the power supply management module.

In an embodiment, the power supply management module is provided with a first branch and a second branch, both the first branch and the second branch have at least one of the power supply output interfaces, the first branch and the second branch are independently controlled, and the first branch and the second branch are respectively connected to different load modules.

In an embodiment, the power distribution system includes two maintenance output modules and two uninterruptible power supplies, each of the maintenance output modules is correspondingly connected with one of the uninterruptible power supplies, and the power supply management module is connected to the two maintenance output modules.

In an embodiment, the power supply management module is further connected with a transfer switch, the transfer switch has two transfer input interfaces, and the two transfer input interfaces are respectively connected to the two maintenance output modules.

In an embodiment, the power distribution module further includes at least one DC power supply module, the DC power supply module is connected to the load, and the DC power supply module is further connected with the maintenance output module.

In an embodiment, the power distribution module further includes a lightning protection module.

In an embodiment, the power distribution module and the maintenance output module are connected in a counter plug manner by counter plug terminals, the maintenance output module and the uninterruptible power supply are connected in a counter plug manner by counter plug terminals, and the maintenance output module and the load module are connected in a counter plug manner by counter plug terminals.

In a second aspect, a power distribution cabinet according to the present disclosure is provided. The power distribution cabinet includes a cabinet body and the above power distribution system, where the power distribution system is arranged in the cabinet body.

In an embodiment, the power distribution module, the maintenance output module, and the uninterruptible power supply are all detachably connected to the cabinet body.

### BRIEF DESCRIPTION OF THE DRAWINGS

Hereinafter, drawings for illustrating embodiments of the present disclosure or the prior art are provided for explain technical solutions of the present disclosure or the prior art more clearly. Obviously, the drawings hereinafter only represent some embodiments of the present disclosure, and those skilled in the art may obtain other drawings based on the drawings without any creative effort.

FIG. 1 is a schematic diagram of a power distribution system according to an embodiment of the present disclosure;

FIG. 2 is a schematic diagram of a power distribution system according to another embodiment of the present disclosure;

FIG. 3 is a three-dimensional structural diagram of a power distribution cabinet according to an embodiment of the present disclosure; and

FIG. 4 is a rear view of a power distribution cabinet according to an embodiment of the present disclosure.

Reference numerals are listed as follows:
10: power distribution system;
110: power distribution module; 111: power distribution general interface; 112: power distribution output interface; 113: power distribution input interface; 114: DC power supply module; 115: lightning protection module; 1151: lightning protection switch; 1152: lightning arrester; 116: device connection terminal; 117: digital interface; 118: electric meter interface;
120: maintenance output module; 121: control switch; 122: first input interface; 123: first output interface; 124: second input interface; 125: second output interface; 126: third output interface;
130: uninterruptible power supply; 131: power supply inlet; 132: power supply outlet;
140: expansion module; 141: expansion input interface; 142: expansion output interface;
150: power supply management module; 151: power supply input interface; 152: power supply output interface;
160: transfer switch; 161: transfer input interface; 162: transfer output interface;
170: first circuit; 180: second circuit; 190: expansion circuit;
20: cabinet body; 210: cabinet door;
30: switch; 40: monitoring host; 50: fan module.

### DETAILED DESCRIPTION

In order to make the objective, the technical solutions and advantages of the embodiments of the present disclosure clear, technical solutions in the embodiments of the present disclosure are described clearly and completely below in conjunction with the drawings of the embodiments of the present disclosure. Apparently, the embodiments described below are only some embodiments rather than all the embodiments of the present disclosure. Any other embodiments obtained by those skilled in the art based on the embodiments in the present disclosure without any creative effort fall within the protection scope of the present disclosure.

With the continuous development of modular data centers, components of the modular data centers are also evolving and iterating. Power distribution systems of the data centers are also developing, and power distribution cabinets have a higher product integration level, a higher intelligent level, is rich in function and more complex, thereby enhancing product competitiveness and better meeting the rapid development requirements of the data centers. A modular power distribution cabinet includes a micro-module level power distribution cabinet or a row-level integrated power distribution cabinet.

Currently, the modularity and high integration of power distribution cabinets in the modular data centers are mainly realized in a centralized design of all power supply and power distribution designs and installation in a rack unit of the cabinet (the rack unit (U) is a most commonly used basic unit in the data center industry for marking a physical space of a cabinet storage device, and is also a basic unit for marking a physical size of a server, a memorizer, a switch and other devices, where 1U is 1.75 inches in height and 19 inches in width). Power supply and power distribution connections for all devices are realized in the power distribution module of the power distribution cabinet, with higher integration, full and complex functions.

In related power distribution cabinet technologies, the power distribution part of the power distribution cabinet is made into a cabinet-integrated power distribution unit. The integration of the power distribution unit is designed based on a cabinet frame of the cabinet. In the power distribution unit, functions such as mains power input, input and output power distribution for uninterruptible power supply, uninterruptible power supply maintenance bypass for uninterruptible power supply, uninterruptible power supply parallel or dual-path redundancy for uninterruptible power supply, power distribution of a cabinet load-level power distribution unit, and system DC power distribution are integrated. Accordingly, all wiring terminals are integrated at a rear side of the power distribution module, and related devices are connected through O-Type Terminals to achieve a final connection with power distribution devices.

Thus, although the modular integration of power distribution in related technologies may adapt to more customer scenarios, the internal design of the power distribution module is complex, the number of device connection terminals is large, the probability of single-point failure inside the power distribution is high, the failure risk of the power distribution system increases, and when a failure occurs in the module, the entire power distribution unit must be disassembled for failure diagnosis, troubleshooting, and analysis, making maintenance complex and costly.

In view of this, according to an embodiment of the present disclosure, a power distribution system is provided. The power distribution system is divided to a combination of multiple modules, reducing the complexity of the power distribution system, reducing the integration level, and reducing the number of connection terminals of the power distribution system to reduce the probability of single-point failure. When a failure occurs in a single module, only the module with the failure is required to be removed for maintenance, without the need to disassemble the entire power distribution system for troubleshooting and analysis, and thus maintenance costs are reduced.

The following is a detailed description of embodiments of the power distribution system 10 of the present disclosure in conjunction with the drawings.

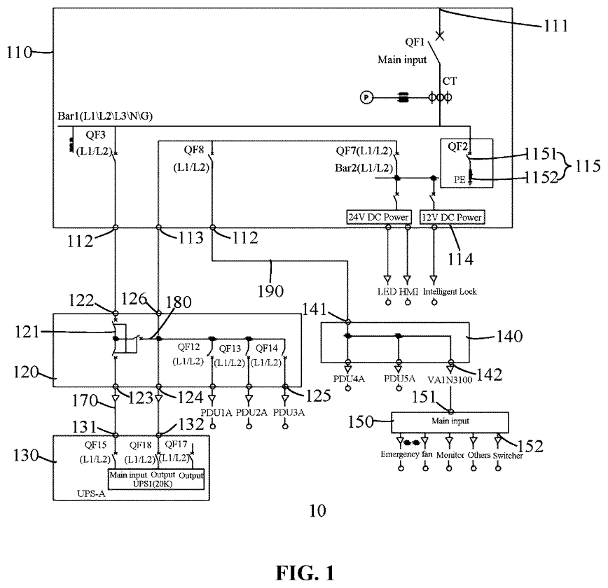

FIG. 1 is a schematic diagram of a power distribution system according to an embodiment of the present disclosure.

As shown in FIG. 1, a power distribution system 10 according to an embodiment of the present disclosure is provided. The power distribution system 10 includes a power distribution module 110, a maintenance output module 120, and an uninterruptible power supply 130. All of the power distribution module 110, the maintenance output module 120, the uninterruptible power supply 130, and a load module have independent module structures. The power distribution module 110 includes a power distribution general interface 111 and a power distribution output interface 112. The power distribution general interface 111 of the power distribution module 110 may be externally connected to a user power supply. Usually, the power distribution general interface 111 is externally connected to a mains power supply, and mains power enters the power distribution module 110 through the power distribution general interface 111 and is delivered from the power distribution output interface 112 of the power distribution module 110.

In the present disclosure, the power distribution output interface 112 of the power distribution module 110 is electrically connected to the maintenance output module 120. The maintenance output module 120 is electrically connected to the uninterruptible power supply 130. The maintenance output module 120 is further electrically connected to the load module.

The user power supply may input electrical energy to the power distribution module 110 through the power distribution general interface 111. The power distribution module 110 is internally provided with a power distribution circuit, and the external electrical energy inputted from the power distribution general interface 111 may be transmitted in the power distribution circuit. The power distribution output interface 112 is connected to the power distribution circuit inside the power distribution module 110, and the power distribution output interface 112 may output electrical energy to the maintenance output module 120.

It should be noted that the maintenance output module 120 has a normal power supply mode and a maintenance mode. When the maintenance output module 120 is in the normal power supply mode, the maintenance output module 120 delivers the electrical energy delivered from the power distribution module 110 to the uninterruptible power supply 130, and then the electrical energy is delivered to the maintenance output module 120 through the uninterruptible power supply 130, and the maintenance output module 120 finally delivers the electrical energy to the load module.

When the maintenance output module 120 is in the maintenance mode, the maintenance output module 120 may directly transmit the electrical energy delivered from the power distribution module 110 to the load module.

In this way, the power distribution system 10 is divided to the power distribution module 110, the maintenance output module 120, and the uninterruptible power supply 130. The three modules are arranged independently from each other, and the power distribution function for the load is achieved through the cooperation of the three modules. Compared to related technologies where all power distribution functions are integrated into a single module, resulting in all wiring terminals being integrated at a rear side of a power distribution unit, the power distribution system 10 according to the present disclosure is divided to three independent modules, and wiring of the power distribution system 10 becomes connections between modules, thereby reducing the wiring complexity of the entire power distribution system 10 and reducing the failure rate of the power distribution system.

In addition, in related technologies, the modules used for power distribution are all integrated in one power distribution unit, which is inconvenient for maintenance when a failure occurs in the power distribution unit. For example, when a failure occurs in the uninterruptible power supply 130, the entire power distribution unit is required to be disassembled. In the power distribution unit, many modules are internally integrated and there are many wirings, and the space for maintenance is limited, increasing the difficulty of maintenance. However, when a failure occurs in a single module of the power distribution system 10 according to the present disclosure, only the module with the failure is required to be inspected, analyzed, and repaired, and the entire power distribution unit is not required to be disassembled for maintenance as in the related technologies, making maintenance more convenient, increasing maintenance efficiency, and reducing maintenance costs.

According to the present disclosure, the uninterruptible power supply 130 and the maintenance output module 120 are arranged independently, so that the uninterruptible power supply 130 and the maintenance output module 120 may be used in combination, and the number of the uninterruptible power supplies 130 and the maintenance output modules 120 may be flexibly configured according to actual conditions, which is beneficial to reduce the user's configuration cost.

Moreover, according to the present disclosure, the maintenance output module 120 is configured such that the load module is connected to the maintenance output module 120. There are two operating mode for the load module. When a failure occurs in the uninterruptible power supply 130, the maintenance output module 120 may be switched to the maintenance mode, and at this time, the power distribution module 110 directly supplies power to the load. Accordingly, when a failure occurs in the uninterruptible power supply 130, the uninterruptible power supply 130 may be repaired while still supplying power to the load.

For example, the power distribution module 110 is configured with an electric meter, an insurance, and a monitoring sensor. The electric meter, the insurance, and the monitoring sensor are located on a main input wiring of the power distribution module 110, and the main input wiring of the power distribution module 110 is connected to the power distribution general interface 111 for transmitting mains power. The electric meter and the monitoring sensor are used to collect and record parameters of the mains power.

For example, to ensure the safety of the power distribution module 110, a lightning protection module 115 is further included in the power distribution module 110. The lightning protection module 115 includes a lightning protection switch 1151 and a lightning arrester 1152. The lightning protection module 115 is connected to a power distribution circuit inside the power distribution module 110 to provide the lightning arrester 1152 with the electrical energy required for its operation.

In addition, the power distribution module 110 may further be provided with an air switch. The air switch plays the role of connecting, disconnecting and carrying a rated operating current in the power distribution module 110. When the circuit or load has overload, short circuit, undervoltage, and other abnormalities, the air switch may quickly cut off the circuit and provide reliable protection, which is beneficial to the electrical safety of the power distribution module 110.

For example, the uninterruptible power supply 130 (UPS) includes at least a converter and an energy storage apparatus (such as a storage battery). The electrical energy is transmitted to the uninterruptible power supply 130 through the maintenance output module 120 and then to the load module, ensuring the continuity of the power on the load module. For example, when a failure occurs in the mains power supply, the load module may be continuously powered by the energy storage apparatus in the uninterruptible power supply 130.

For example, both the maintenance output module 120 and the uninterruptible power supply 130 are provided with multiple input and output interfaces, and the maintenance output module 120 may be connected to the power distribution module 110, the load module, and the uninterruptible power supply 130 through the input and output interfaces.

For example, there are multiple interface on the maintenance output module 120 for connecting the load module, and each of the interfaces may be connected to the load.

In some possible embodiments, referring to FIG. 1, the external electrical energy of the power distribution module 110 may be transmitted to the load through the maintenance output module 120. The maintenance output module 120 has two operating modes (a normal power supply mode and a maintenance mode). In both modes, the maintenance output module 120 may distribute power to the load module. The difference is that in the normal power supply mode, the maintenance output module 120 and the uninterruptible power supply 130 cooperate to distribute power to ensure stable power distribution to the load, while in the maintenance mode, the maintenance output module 120 directly delivers the electrical energy provided by the power distribution module 110 to the load module.

To implement the two operating modes of the maintenance output module 120, a first circuit 170 and a second circuit 180 are connected between the maintenance output module 120 and the load module. Electrical energy may be transmitted to the load module through the first circuit 170 or the second circuit 180.

It should be noted that both the first circuit 170 and the second circuit 180 are connected to the power distribution module 110. The power distribution module 110 may transmit electrical energy to the first circuit 170 and the second circuit 180. One of the first circuit 170 and the second circuit 180 may implement the normal power supply mode of the maintenance output module 120, and the other may implement the maintenance mode of the maintenance output module 120. According to the embodiment of the present disclosure, for example, the uninterruptible power supply 130 may be connected to the first circuit 170, enabling the first circuit 170 to implement the normal power supply mode of the maintenance output module 120.

For example, to ensure that the first circuit 170 and the second circuit 180 do not interfere with each other, the first circuit 170 and the second circuit 180 are arranged in parallel, ensuring that if one of the two circuits fails, the normal operation of the other circuit is not affected. By operating the maintenance output module 120, on and off of the first circuit 170 and the second circuit 180 may be controlled, enabling the maintenance output module 120 to switch between the two operating modes.

For example, the first circuit 170 and the second circuit 180 may be connected to the power distribution module 110 respectively. For example, the power distribution module 110 is provided with multiple power distribution output interfaces 112, and the first circuit 170 and the second circuit 180 are respectively connected to two different power distribution output interfaces 112.

Alternatively, to reduce the complexity of wiring, the first circuit 170 and the second circuit 180 may be connected to a same power distribution output interface 112 of the power distribution module 110. In this case, a wire is extended from the power distribution output interface 112, and both the first circuit 170 and the second circuit 180 are connected to the wire.

When controlling the on and off of the first circuit 170 and the second circuit 180, switch structures may be arranged on the first circuit 170 and the second circuit 180, respectively. The switch structures on the first circuit 170 and the second circuit 180 may control the on and off of the respective circuits.

In some possible embodiments, to simplify the structure, one switch may be used to control the on and off of the first circuit 170 and the second circuit 180. For example, the maintenance output module 120 further includes a control switch 121. The control switch 121, for example, may be a single-pole double-throw switch. The control switch 121 is connected between the first circuit 170 and the second circuit 180 and controls the on and off of the first circuit 170 and the second circuit 180.

For example, when the first circuit 170 and the second circuit 180 are connected to the same power distribution output interface 112 through the same wire, the control switch 121 may be arranged at a connection point where the first circuit 170 and the second circuit 180 connected with the wire. One electric connection terminal of the control switch 121 is connected to the power distribution output interface 112 through the wire, and the control switch 121 has at least two electric output terminals, connected to the first circuit 170 and the second circuit 180, respectively. The control switch 121 may control the electric connection between the electric connection terminal and one of the electric output terminals, thereby controlling whether the first circuit 170 or the second circuit 180 is electrically connected to the power distribution output interface 112.

In some embodiments, the multiple input interfaces on the maintenance output module 120 may include a first input interface 122 and a second input interface 124. The output interfaces on the maintenance output module 120 may include a first output interface 123 and a second output interface 125. The uninterruptible power supply 130 includes a power supply inlet 131 and a power supply outlet 132.

The first input interface 122 of the maintenance output module 120 may be electrically connected to the power distribution output interface 112 of the power distribution module 110. The first input interface 122 may be electrically connected to the first output interface 123 inside the maintenance output module 120. The first output interface 123 is connected to the power supply inlet 131 of the uninterruptible power supply 130 through electrical connectors such as wires. The power supply inlet 131 and the power supply outlet 132 of the uninterruptible power supply 130 are internally connected by a circuit for transmitting electrical energy. It should be noted that the circuit formed by the connections between the power distribution output interface 112, the first input interface 122, the first output interface 123, the power supply inlet 131, and the power supply outlet 132 may already form the first circuit 170. At this point, the load may be directly connected to the power supply outlet 132 of the uninterruptible power supply 130 such that stable electrical energy is provided to the load.

In some possible embodiments, the power supply outlet 132 of the uninterruptible power supply 130 may further be electrically connected to the second input interface 124 of the maintenance output module 120. The second input interface 124 is electrically connected to the second output interface 125 inside the maintenance output module 120, and the load may be electrically connected to the second output interface 125. At this point, the circuit formed by the connections between the power distribution output interface 112, the first input interface 122, the first output interface 123, the power supply inlet 131, the power supply outlet 132, the second input interface 124, and the second output interface 125 may form the first circuit 170, providing electrical energy to the load.

It should be noted that the maintenance output module 120 typically has multiple second output interfaces 125 to connect multiple loads, enabling simultaneous power supply to multiple loads. The second input interface 124 and the multiple second output interfaces 125 are connected by wires. The wire extending from the second input interface 124 may split into multiple branches, and each of the branches is connected to a corresponding second output interface 125.

For example, the maintenance output module 120 is provided with multiple first input interfaces 122, and the first circuit 170 and the second circuit 180 may be connected to different first input interfaces 122. A wire may be brough out from one power distribution output interface 112 to be connected to two first input interfaces 122.

For example, the maintenance output module 120 is provided with one first input interface 122. The power distribution output interface 112 is connected to the first input interface 122. A terminal of the first circuit 170 and a terminal of the second circuit 180 may be connected at a node inside the maintenance output module 120, and the node is connected to the first input interface 122. The other terminal of the first circuit 170 and the other terminal of the second circuit 180 may be connected at a node inside the maintenance output module 120, and the node is connected to the second output interface 125 through a wire.

The number of the second output interfaces 125 of the maintenance output module 120 for connecting loads is limited. When the number of loads requiring power distribution is too large, the second output interfaces 125 of the maintenance output module 120 fail to meet the demand for simultaneous power distribution to all loads. Therefore, in some possible embodiments, power distribution structures used for power distribution to loads may be added to implement simultaneous power distribution to a larger number of loads. For example, the power distribution system 10 may further include an expansion module 140. The expansion module 140 includes an expansion output interface 142 for connecting a load. The expansion module 140 is provided with multiple expansion output interfaces 142, and each of the expansion output interfaces 142 is connected to a load to implement power distribution to the load. The expansion module 140 may further include an expansion input interface 141. The expansion input interface 141 is configured to receive electrical energy. The expansion input interface 141 and the expansion output interface 142 are electrically connected inside the expansion module 140, making the electrical energy inputted through the expansion input interface 141 to be delivered through the expansion output interface 142.

For example, the expansion module 140 may be electrically connected to the second output interface 125 of the maintenance output module 120 through the expansion output interface 142, so that the maintenance output module 120 may supply power to the expansion module 140 in both the normal power supply mode and the maintenance mode.

In some possible embodiments, as shown in FIG. 1, the power distribution module 110 may implement power distribution to DC devices in the power distribution system. For example, the DC devices on the power distribution module 110 include a power indicator, a light, an ambient light, a smart lock, a micro switch, and the like. To implement power distribution to these DC devices, a DC power supply is required. Therefore, the power distribution module 110 further includes at least one DC power supply module 114 internally. The power output of the DC power supply module 114 may be connected to the DC devices to supply power to the DC devices.

To provide stable and continuous electrical energy to the DC power supply module 114, the DC power supply module 114 is further connected with the maintenance output module 120. Specifically, the maintenance output module 120 is further provided with a third output interface 126, and the power distribution module 110 is provided with a power distribution input interface 113. The third output interface 126 of the maintenance output module 120 is connected to the power distribution input interface 113. The power distribution input interface 113 is connected to the DC power supply module 114 inside the power distribution module 110. The third output interface 126 is connected to the first circuit 170, allowing the electrical energy processed by the uninterruptible power supply 130 to be transmitted to the third output interface 126, thereby providing stable electrical energy to the DC power supply module 114. The DC power supply module 114, as a DC voltage stabilization structure, may convert AC power transmitted by the power distribution input interface 113 into DC power through a DC conversion circuit of the DC power supply module 114, thereby supplying power to the DC devices.

It should be noted that, to ensure that the DC power supply module 114 may still be powered when a failure occurs in the uninterruptible power supply 130, the third output interface 126 may further be connected to the second circuit 180. When a failure occurs in the uninterruptible power supply 130, the third output interface 126 may be directly powered through the second circuit 180.

For example, the terminals of the first circuit 170 and the second circuit 180 connected to the second output interface 125 may be connected at a node, and the third output interface 126 may be connected to the node between the first circuit 170 and the second circuit 180 through a wire.

In some possible embodiments, to avoid occupying the second output interface 125 on the maintenance output module 120 to be directly connected to the load, the expansion module 140 may further be connected to the power distribution module 110 through an expansion circuit 190. When the maintenance output module 120 supplies power to the DC power supply module 114 of the power distribution module 110, the maintenance output module 120 may supply power to the expansion module 140.

For example, the power distribution module 110 is provided with multiple power distribution output interfaces 112. One of the power distribution output interfaces 112 is connected to the expansion input interface 141 of the expansion module 140 through the expansion circuit 190. The power distribution output interface 112 may further be connected to a connection circuit between the power distribution input interface 113 and the DC power supply module 114 of the power distribution module 110. In this way, when the electrical energy transmitted from the maintenance output module 120 to the power distribution input interface 113 is transmitted to the DC power supply module 114, the electrical energy may split to the expansion module 140 to implement power distribution to the load connected to the expansion module 140.

Thus, when the maintenance output module 120 is in the normal power supply mode, the maintenance output module delivers the electrical energy delivered from the power distribution module 110 to the uninterruptible power supply 130, and then delivered to the maintenance output module 120 through the uninterruptible power supply 130, and the maintenance output module 120 finally delivers the electrical energy to the expansion circuit 190, resulting in power distribution to the load on the expansion module 140.

When the maintenance output module 120 is in the maintenance mode, the maintenance output module 120 may directly transmit the electrical energy delivered from the power distribution module 110 to the expansion circuit 190.

In some possible embodiments, a circuit breaker is arranged between the power distribution general interface 111 and the power distribution output interface 112 to control the on and off of the circuit between the power distribution general interface 111 and the power distribution output interface 112. A circuit breaker is further arranged in the circuit of the first circuit 170 and the second circuit 180 that implement power distribution to the second output interface 125. When there are multiple second output interfaces 125, each of the second output interfaces 125 is provided with a circuit breaker.

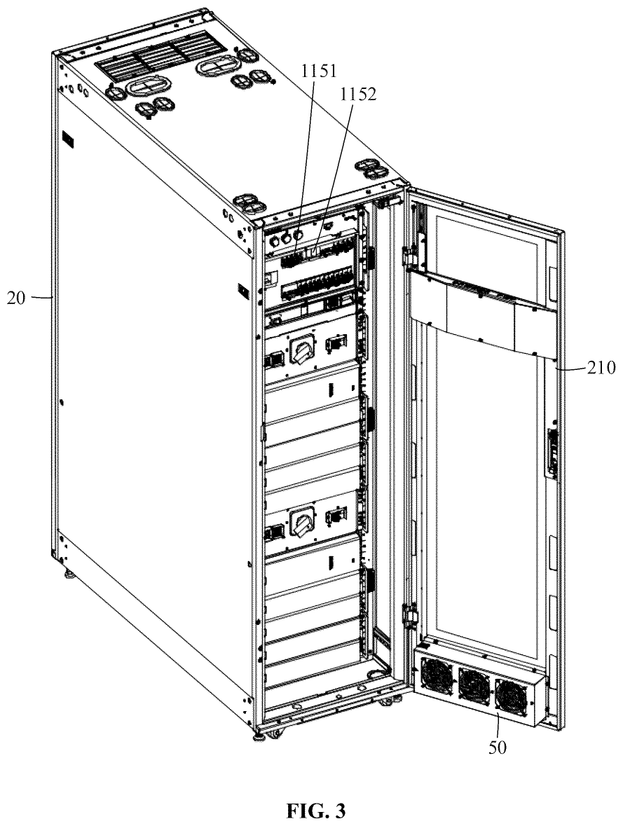

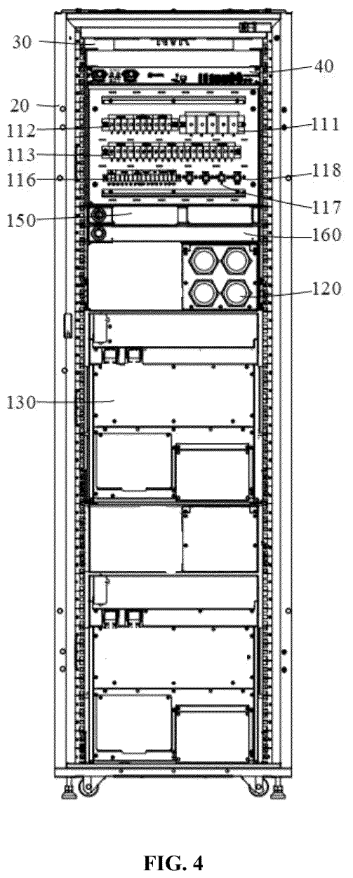

FIG. 3 is a three-dimensional structural diagram of a power distribution cabinet according to an embodiment of the present disclosure. FIG. 4 is a rear view of a power distribution cabinet according to an embodiment of the present disclosure.

As shown in FIG. 1, FIG. 3 and FIG. 4, in some possible embodiments, to meet the power distribution requirements of the power distribution module 110 for DC devices, the power distribution module 110 is further provided with a device connection terminal 116. The DC devices may be connected to the power distribution module 110 through the device connection terminal 116. In addition, the power distribution module 110 is further provided with a digital interface 117 connected to a surge protector and other electrical devices, and an electric meter interface 118. The power distribution output interface 112, the power distribution input interface 113, the device connection terminal 116, the digital interface 117, and the electric meter interface 118 form a cascaded interface integrated into the power distribution module 110, implementing the cascading of devices within a row-level cabinet.

For example, the interfaces between the modules, as well as the interfaces between the load and the module, are connected in a counter plug manner by counter plug terminals. The counter plug manner for connecting two modules or connecting a module and a load facilitates an on-site installation of the modules of the power distribution system 10 and simplifies the connection of various power distribution devices within the cabinet to the power distribution system 10, thereby improving on-site installation efficiency.

In some possible embodiments, the power distribution cabinet is further provided with other functional modules, such as a switch 30, a monitoring module, and an emergency fan for heat dissipation. To supply power to an emergency fan module 50, the switch 30, and the monitoring module, as well as to manage the control of the modules, the power distribution system 10 further includes a power supply management module 150. The power supply management module 150 is provided with a power supply input interface 151 and a power supply output interfaces 152. The power supply input interface 151 is configured to transmit external electric energy to the power supply management module 150, and the power supply output interfaces 152 is connected to the switch 30, the fan module 50, and the monitoring module to transmit electric energy to the fan module 50 and the like.

For example, the power supply input interface 151 of the power supply management module 150 may be connected to the expansion module 140 or the maintenance output module 120. When the power supply management module 150 is connected to the expansion module 140, the power supply input interface 151 is connected to the expansion output interface 142 of the expansion module 140. When the power supply management module 150 is connected to the maintenance output module 120, the power supply input interface 151 is connected to the second output interface 125 of the maintenance output module 120. In this way, stable and continuous electric energy may be provided to the power supply management module 150 through the maintenance output module 120 or the expansion module 140.

For example, the power supply management module 150 has multiple power supply output interfaces 152. The multiple power supply output interfaces 152 may be connected to the fan module 50, the switch 30, and the monitoring module, respectively.

In some possible embodiments, the fan module 50 may be provided with multiple fan structures, and each of the fan structures is connected to a power supply output interface 152, implementing individual control for each of the fan structures, and turning on or off a corresponding number of fans based on actual needs.

The fan module 50 is typically configured to be turned off by default, and the power supply management module 150 controls the fan module to be turned on only when the fan is required to be turned on. Therefore, the power supply management module 150 may be divided to two control sections: one for controlling the fan module 50 and the other for controlling devices such as the switch 30 and the monitoring module.

For example, the power supply management module 150 is internally provided with a first branch and a second branch. Both the first branch and the second branch have at least one power supply output interface 152. The electrical energy inputted through the power supply input interface 151 may be transmitted through the first branch and the second branch. The first branch and the second branch are independently controlled, and are connected to different load modules.

For example, the fan module 50 is connected to the first branch, and the monitoring module and the switch 30 are connected to the second branch. The first branch may supply power to the fan module 50 and provide an on and off management function for the fan module 50. For example, the power supply management module 150 is provided with a circuit board preset with a control program to control the on and off of the fan module 50.

The switch 30 and the monitoring module are connected to the second branch, and the second branch may supply power to the switch 30 and the monitoring module.

In related technologies, it is required to provide respective cabinet-level power distribution units for supplying power to the fan module 50, the monitoring module and the switch 30, increasing system configuration and costs. According to the present disclosure, the power supply management module 150 is provided, and the power supply management module 150 has independent first and second branches. The first branch and the second branch are independently controlled, with the first branch controlling and managing the fan module 50 and the second branch controlling and managing the switch 30 and the monitoring module, thereby enabling a single module to perform the functions of multiple systems, reducing the number of power distribution devices in the system and saving costs.

In a case that the power distribution system 10 adopts a dual-path power distribution architecture, the related technologies fail to implement an independent dual-path redundancy design, so that when a failure occurs in one uninterruptible power supply 130, the monitoring module and the switch 30 in the system cannot operate normally until the failure is repaired. Therefore, there is a shortcoming in the design of the solution in related technologies.

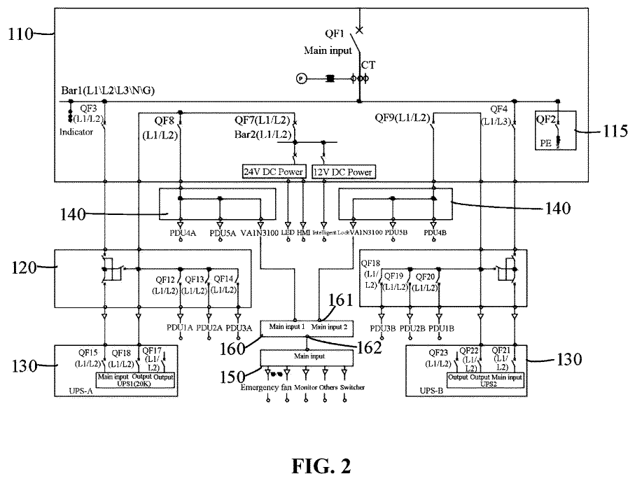

FIG. 2 is a schematic diagram of a power distribution system according to another embodiment of the present disclosure.

As shown in FIG. 1 and FIG. 2, in some possible embodiments, the maintenance output module 120 and the uninterruptible power supply 130 in the present disclosure are typically used together, with one maintenance output module 120 paired with one uninterruptible power supply 130. In the embodiment, the power distribution system 10 includes two pairs of maintenance output modules 120 and uninterruptible power supplies 130, such as two maintenance output modules 120 and two uninterruptible power supplies 130.

Referring to FIG. 2, each of the maintenance output modules 120 is connected to one corresponding uninterruptible power supply 130. The configuration between each pair of maintenance output module 120 and uninterruptible power supply 130 and the power distribution module 110 is consistent, such as including the first circuit 170 and the second circuit 180, with a same connection method for the first circuit 170 and the second circuit 180. The power supply input interface 151 of the power supply management module 150 is respectively connected to second output interfaces 125 of the two maintenance output modules 120.

Alternatively, the power distribution module 110 is provided with two expansion modules 140, and each of the two expansion modules 140 is connected to one corresponding maintenance output module 120. The power supply input interface 151 of the power supply management module 150 is respectively connected to the two expansion modules 140.

By arranging two pairs of maintenance output modules 120 and uninterruptible power supplies 130, the power distribution system 10 achieves a dual-path backup configuration, implementing power distribution input of dual-path uninterruptible power supplies 130 to the power supply management module 150. When a failure occurs in one uninterruptible power supply 130, the power supply of the other uninterruptible power supply 130 is not affected, and the second circuit 180 between the maintenance output module 120 and the power distribution module 110 may continue to supply power to the power supply management module 150, ensuring normal operation of the power supply management module 150.

In some possible embodiments, to facilitate the provision of a dual-path power supply to the power supply management module 150, the power distribution system 10 further includes a transfer switch 160. The transfer switch 160 includes a transfer input interface 161 and a transfer output interface 162. The transfer output interface 162 of the transfer switch 160 is connected to the power supply input interface 151. The transfer switch 160 has multiple transfer input interfaces 161, two of the transfer input interfaces 161 may be respectively connected to one maintenance output module 120. Alternatively, when the power distribution system 10 is provided with the expansion modules 140, the transfer input interfaces 161 are connected to the expansion output interfaces 142 of the expansion modules 140.

For example, the transfer switch 160 and the expansion module 140 are connected in a counter plug manner by counter plug terminals; the transfer switch 160 and the maintenance output module 120 are connected in a counter plug manner by counter plug terminals; and the transfer switch 160 and the power supply management module 150 are connected in a counter plug manner by counter plug terminals, facilitating installation and removal.

A power distribution cabinet according to the present disclosure is further provided. As shown in FIG. 3 and FIG. 4, the power distribution cabinet includes a cabinet body 20 and the aforementioned power distribution system 10, and the power distribution system 10 is arranged in the cabinet body 20.

The cabinet body 20 of the power distribution cabinet is provided with a rack unit, and the power distribution module 110, the maintenance output module 120, and the uninterruptible power supply 130 are all arranged within the rack unit of the cabinet body 20.

In some possible embodiments, the power distribution module 110, the maintenance output module 120, the uninterruptible power supply 130, the expansion module 140, the transfer switch 160, and the power supply management module 150 all adopt a rack-mounted structure. For example, these modules may be all provided with an outer shell, with functional structures integrated into their respective outer shells. The modules are then plugged into the rack unit space of the cabinet body 20, so that the modules are detachably connected to the cabinet body 20.

For example, the top of the rack unit (U) space of the cabinet body 20 reserves 2U space for installing the switch 30 and a monitoring host 40 of the power distribution cabinet. The power distribution module 110, the maintenance output module 120, and the uninterruptible power supply 130 are installed within the rack unit space of the cabinet body 20 in sequence from top to bottom.

For example, the cabinet body 20 is provided with a cabinet door 210 that may be opened and closed. When the cabinet door 210 is closed, all the modules are shielded within the cabinet body 20. When the cabinet door 210 is opened, the switch structures on the modules may be operated.

For example, a smart lighting switch and a manual switch are integrated in the power distribution module 110. By manually toggling the manual switch, the smart lighting switch may be turned on or off. In addition, the lightning arrester 1152 may be turned on or off by manually toggling the lightning protection switch 1151.

For example, to prevent accidental contact with the switches on the power distribution module 110, a transparent protective cover may be arranged on the front panel of the power distribution module 110. To prevent electric shock, a rear cover may be arranged on the back of the power distribution module 110 to shield the wiring positions.

For example, to reduce the risk of the single-point failure of the power distribution system 10 and improve maintenance portability, one or two uninterruptible power supplies 130 and maintenance output modules 120 may be arranged inside the cabinet. The maintenance output module 120 is used in conjunction with the uninterruptible power supply 130, providing both a maintenance bypass mode and an inverter output mode for the uninterruptible power supply 130. Furthermore, the maintenance output module 120 is provided with multiple output interfaces for plugging into the cabinet-level power distribution module 110. A User may flexibly configure single-path or dual-path power distribution architectures based on the importance of the system's power distribution, synchronously configuring different uninterruptible power supplies 130 and maintenance output modules 120 to reduce costs and facilitate installation, operation, and maintenance.

For example, the fan module 50 may be arranged on the inner surface of the cabinet door 210 towards the interior of the cabinet body 20, and positioned at the bottom of the cabinet door 210. The cabinet door 210 may be provided with one or more fan modules 50, and each of the fan modules 50 may be provided with multiple sets of fans, all powered by the power supply management module 150. When the number of high-temperature alarms in the cabinet in the system exceeds one, the monitoring module triggers the power supply management module 150 to control the switch of the first branch, turning on all emergency fan modules 50 in the system to provide temporary cooling before a user or maintenance team arrive on-site for troubleshooting and problem resolution.

Finally, it should be stated that: the above embodiments are only intended for illustrating the technical solutions of the present disclosure rather than limiting the present disclosure. Although the present disclosure is illustrated in detail with reference to the embodiments described above, it should be understood by those skilled in the art that, modifications can still be made to the technical solutions recited in the embodiments described above, or equivalent substitutions can be made to a part or all of the technical features of the technical solution. Such modifications or substitutions will not cause the essence of corresponding technical solutions to depart from the scope of the technical solutions of the embodiments of the present disclosure.

What is claimed is:

1. A power distribution system, comprising a power distribution module, a maintenance output module, and an uninterruptible power supply; wherein
the power distribution module comprises a power distribution general interface and a power distribution output interface;
the power distribution output interface of the power distribution module is electrically connected to the maintenance output module, the maintenance output module is electrically connected to the uninterruptible power supply, and the maintenance output module is further electrically connected to a load module;
the power distribution general interface is externally connected to a power supply device, the power distribution output interface outputs electrical energy to the maintenance output module, and the maintenance output module has a normal power supply mode and a maintenance mode;
when the maintenance output module is in the normal power supply mode, the maintenance output module delivers the electrical energy delivered from the power distribution module to the uninterruptible power supply, and then the electrical energy is delivered to the maintenance output module through the uninterruptible power supply, and the maintenance output module finally delivers the electrical energy to the load module; and
when the maintenance output module is in the maintenance mode, the maintenance output module directly delivers the electrical energy delivered from the power distribution module to the load module.

2. The power distribution system according to claim 1, wherein a first circuit and a second circuit are connected between the maintenance output module and the load module, the first circuit and the second circuit are arranged in parallel, the uninterruptible power supply is connected to the first circuit, and the maintenance output module is configured to control on and off of the first circuit and the second circuit.

3. The power distribution system according to claim 2, wherein the maintenance output module further comprises a control switch, the control switch is connected between the first circuit and the second circuit, and the control switch is configured to control the on and off of the first circuit and the second circuit.

4. The power distribution system according to claim 1, further comprising an expansion module; wherein the expansion module has an expansion output interface for connecting a load, and the expansion module and the power distribution module are connected through an expansion circuit, so that the power distribution module is configured to distribute power to the expansion module through the expansion circuit.

5. The power distribution system according to claim 4, wherein the expansion circuit is connected to the maintenance output module; when the maintenance output module is in the normal power supply mode, the maintenance output module delivers the electrical energy delivered from the power distribution module to the uninterruptible power supply, and then the electrical energy is delivered to the maintenance output module through the uninterruptible power supply, and the maintenance output module finally delivers the electrical energy to the expansion circuit; and
when the maintenance output module is in the maintenance mode, the maintenance output module directly delivers the electrical energy delivered from the power distribution module to the expansion circuit.

6. The power distribution system according to claim 4, further comprising a power supply management module, wherein the power supply management module is connected to the expansion module or the maintenance output module, the power supply management module has a plurality of power supply output interfaces, the plurality of power supply output interfaces are connected to the load module, and the expansion module or the maintenance output module supplies power to the power supply management module.

7. The power distribution system according to claim 6, wherein the power supply management module is provided with a first branch and a second branch, both the first branch and the second branch have at least one of the power supply output interfaces, the first branch and the second branch are independently controlled, and the first branch and the second branch are respectively connected to different load modules.

8. The power distribution system according to claim 6, wherein the power distribution system comprises two maintenance output modules and two uninterruptible power supplies, each of the maintenance output modules is correspondingly connected with one of the uninterruptible power supplies, and the power supply management module is connected to the two maintenance output modules.

9. The power distribution system according to claim 7, wherein the power distribution system comprises two maintenance output modules and two uninterruptible power supplies, each of the maintenance output modules is correspondingly connected with one of the uninterruptible power supplies, and the power supply management module is connected to the two maintenance output modules.

10. The power distribution system according to claim 8, wherein the power supply management module is further connected with a transfer switch, the transfer switch has two transfer input interfaces, and the two transfer input interfaces are respectively connected to the two maintenance output modules.

11. The power distribution system according to claim 9, wherein the power supply management module is further connected with a transfer switch, the transfer switch has two transfer input interfaces, and the two transfer input interfaces are respectively connected to the two maintenance output modules.

12. The power distribution system according to claim 1, wherein the power distribution module further comprises at least one DC power supply module, the DC power supply module is connected to a load, and the DC power supply module is further connected with the maintenance output module.

13. The power distribution system according to claim 1, wherein the power distribution module further comprises a lightning protection module.

14. The power distribution system according to claim 1, wherein the power distribution module and the maintenance output module are connected in a counter plug manner by counter plug terminals, the maintenance output module and the uninterruptible power supply are connected in a counter plug manner by counter plug terminals, and the maintenance output module and the load module are connected in a counter plug manner by counter plug terminals.

15. A power distribution cabinet, comprising a cabinet body and the power distribution system according to claim 1, wherein the power distribution system is arranged in the cabinet body.

16. The power distribution cabinet according to claim 15, wherein the power distribution module, the maintenance output module, and the uninterruptible power supply are all detachably connected to the cabinet body.
